(19) United States
(12) Patent Application Publication
(10) Pub. No.: US 2025/0252225 A1
(43) Pub. Date: Aug. 7, 2025

(54) METHOD OF MECHANISM GENERATION BASED ON TRAJECTORY

(71) Applicant: FENG CHIA UNIVERSITY, Taichung City (TW)

(72) Inventors: Yee Siang GAN, Taichung City (TW); Yu-Ting SHENG, Taichung City (TW); Sze-Teng LIONG, Taichung City (TW); Shih-Yuan WANG, Taichung City (TW); Ting-Chia CHEN, Taichung City (TW)

(21) Appl. No.: 18/987,517

(22) Filed: Dec. 19, 2024

(30) Foreign Application Priority Data
Feb. 7, 2024 (TW) 113104990

(51) Int. Cl. G06F 30/10; G06F 30/27

(52) U.S. Cl. CPC G06F 30/10; G06F 30/27

(57) ABSTRACT

A method of mechanism generation based on trajectory includes the following steps: step A: generating plural augmented trajectories based on an initial trajectory, and collecting plural pieces of motion trajectory data from the initial trajectory and the augmented trajectories; step B: screening each piece of motion trajectory data according to a screening criterion in order to eliminate motion trajectory data falling short of the screening criterion; step C: forming a diagram by blending motion trajectory data conforming to the screening criterion, wherein the diagram includes at least two nodes and at least one connecting line connecting the two nodes, each node includes a physical feature, and the connecting line includes a dynamic characteristic between the two nodes; and step D: constructing a three-dimensional mechanism based on the physical features and the dynamic characteristic.

### BACKGROUND OF THE INVENTION

### 1. Technical Field

The present invention relates to a data processing technique and more particularly to a method of mechanism generation based on a trajectory.

### 2. Description of Related Art

Traditionally, mechanism design is generally based on geometry, or more particularly on calculations of such parameters as the shape, dimensions, and positions of a physical model. The calculation process takes a lot of labor and time as it deals with model construction, analysis, and optimization, and the accuracy of the calculation results depends on the quality of the model constructed and the experiences of the engineers involved. As such, the conventional mechanism design techniques have the following shortcomings:

1. A time-consuming complicated process flow: A conventional process flow of mechanism design includes such steps as choosing an appropriate mechanism prototype and fine-tuning the dimensions of each component and therefore takes a considerable amount of time and effort.

2. Difficulty in design modification: If a product design needs modification, it is necessary to re-create the three-dimensional shape of the product or conduct a complex fine-tuning procedure. This means that even a minor change in design may require much time and effort. Consequently, design modification is difficult and time-consuming, not to mention that the intended design effect cannot be guaranteed.

To improve the foregoing problems, computer-aided design techniques have been developed. For example, Taiwan Published Invention patent application No. 202147160A discloses adjusting a three-dimensional model in real time mainly by changing its shape parameters so that the three-dimensional model need not be re-created each time modification is required, the objective being to save time.

In the afore-cited patent application, the three-dimensional model is changed by adjusting the shape parameters intuitively, but this method has its limitations, especially when dealing with a complicated design change, which still calls for manual adjustment and modification by the designer or engineer, and whose corresponding modification process fails to take into account factors other than the shape parameters, such as motion, actuation, and linked movements. These factors cannot be determined simply by adjusting the shape parameters.

In addition, when it comes to data processing, genetic algorithms are typically used, but the iterative optimization process tends to be time-consuming and inefficient and therefore necessitates further improvement.

### BRIEF SUMMARY OF THE INVENTION

The primary objective of the present invention is to provide a method of mechanism generation based on a trajectory. The method constitutes a disruptive change to the conventional mechanism design methods by using a motion trajectory as the basis of mechanism design so that the three-dimensional mechanism derived from computation and data processing has the required features in terms of motion, actuation, and so on and can better meet practical needs than if designed in a conventional manner.

Another objective of the present invention is to generate a large amount of data rapidly by augmenting a motion trajectory. The data generated serves to establish the relationships between the geometric parameters of a mechanism and the motion trajectories generated, and this helps produce, by way of training, a model with better prediction ability than if the model is created in a conventional manner.

To achieve the foregoing objectives, the present invention provides a method of mechanism generation based on a trajectory, and the method includes the following steps:
Step A: generating a plurality of augmented trajectories based on an initial trajectory, and collecting a plurality of pieces of motion trajectory data from the initial trajectory and the augmented trajectories;
Step B: screening each piece of motion trajectory data according to a screening criterion in order to eliminate motion trajectory data that does not conform to the screening criterion;
Step C: forming a diagram by blending motion trajectory data that conforms to the screening criterion, wherein the diagram includes at least two nodes and at least one connecting line connecting the two nodes, each node includes a physical feature, and the connecting line includes a dynamic characteristic between the two nodes; and
Step D: constructing a three-dimensional mechanism based on the physical features and the dynamic characteristic.

In one embodiment, each piece of motion trajectory data in step A is a target-trajectory data, an anchor point coordinate, or an actual-executed-trajectory data, and the blending in step C involves creating a trajectory plot based on the target-trajectory data, the actual-executed-trajectory data, and the anchor point coordinate in the motion trajectory data that conforms to the screening criterion, and then combining or integrating the multiple sets of coordinates in the trajectory plot to obtain the diagram.

In one embodiment, each augmented trajectory in step A is generated by varying the initial trajectory according to a variate standard and calculating the average values, maximum values, or minimum values of the resulting variation of the initial trajectory.

In one embodiment, the variate standard is applied by setting the domain of a random radius differently so as to obtain the calculation results of the average values, maximum values, or minimum values. When calculating the average values, the domain of the random radius is set as from 1 to 5.4; when calculating the minimum values, the domain of the random radius is set as from 1 to 1.6; and when calculating the maximum values, the domain of the random radius is set as from 1 to 11.2.

In one embodiment, the screening criterion in step B is applied by determining whether or not there is a non-closed trajectory and whether or not an actuator is deformed.

In one embodiment, each of the physical features is a shape, a length, a height, or a width.

In one embodiment, the dynamic characteristic is a speed, an acceleration, a displacement, a force, a mass, a momentum, an angular velocity, a moment of inertia, or an angular acceleration.

In one embodiment, the method further includes a step E to be performed after step D, and step E includes inputting the three-dimensional mechanism into a deep learning model in order to train the deep learning model and thereby obtain a trained deep learning model.

In one embodiment, the method further includes a step F to be performed after step E, and step F includes evaluating the trained deep learning model.

In one embodiment, the method further includes a step G to be performed after step E, and step G includes allowing a user to input a target trajectory into the trained deep learning model in order for the trained deep learning model to generate data of a target mechanism.

In contrast to the conventional mechanism design techniques, the method of the present invention does not need a complicated geometric structure to be defined in advance, does not require a lot of time to be spent fine-tuning shape parameters, but can nevertheless design and generate, in a highly efficient and accurate manner, target-mechanism data that conforms to a target trajectory, thereby increasing the efficiency and cost effectiveness of the design process significantly, reducing the waste material and energy consumption in actual production, and thus contributing to both environmental protection and economic development.

In addition, the present invention further has at least the following applications:

1. The present invention supports the design of highly customized products and is particularly suitable for use in industries where personalized solutions are desired. For example, the invention can be used for complex parts in the automotive industry, for medical devices and rehabilitation instruments, for consumer electronics, and for interior design. The invention is also expected to have positive effect on the progress and development in such fields as construction, machines, and engineering.

2. The present invention enables enterprises to innovate on the basis of big data. In particular, during the product development and engineering design process, the invention can assist in supply chain management and help reduce the inventory cost and enhance supply chain efficiency through precise machine part prediction and design optimization, thereby providing enterprises with a strong competitive edge.

3. The present invention can be provided in a software-as-a-service (SaaS) mode so that enterprises of all sizes can access advanced machine design tools through a cloud-based platform. This greatly enhances the accessibility of design resources and flexibility in design.

4. The present invention can be incorporated with such advanced manufacturing techniques as three-dimensional printing to further accelerate the transformation from concepts to physical products. The invention is especially suitable for the rapid manufacture of complicated products and prototypes.

### BRIEF DESCRIPTION OF THE SEVERAL VIEWS OF THE DRAWINGS

FIG. 1 is the flowchart of a preferred embodiment of the present invention.

FIG. 2 schematically shows an initial trajectory in the invention.

FIG. 3 schematically shows an augmented trajectory in the invention that is used for calculating minimum values.

FIG. 4 schematically shows an augmented trajectory in the invention that is used for calculating average values.

FIG. 5 schematically shows an augmented trajectory in the invention that is used for calculating maximum values.

FIG. 6 schematically shows how motion trajectory data is converted into a graphic language according to the invention.

### DETAILED DESCRIPTION OF THE INVENTION

A preferred embodiment of the present invention provides a method of mechanism generation based on a trajectory. The method uses Rhino Grasshopper software and a Kangaroo physics engine to carry out computation and the related operations but is not limited to the use of this software and physics engine. Other computer program software and physics engines may be used as appropriate.

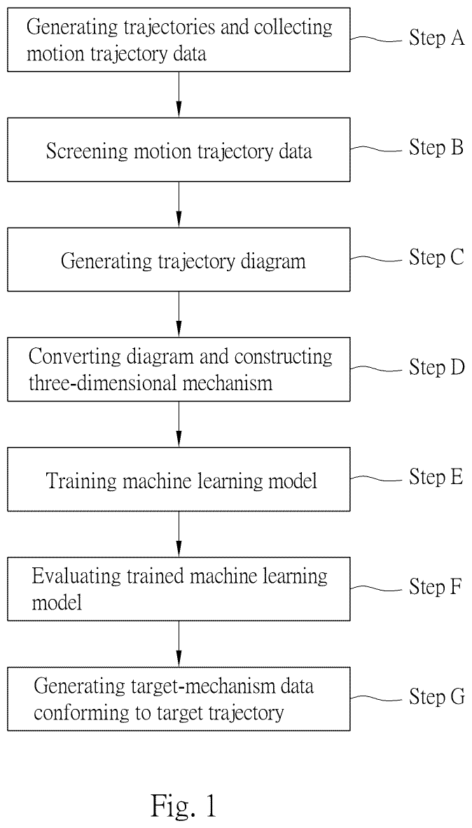

Referring to FIG. 1, the method includes the following steps:

Step A: A plurality of augmented trajectories are generated according to an initial trajectory, and a plurality of pieces of motion trajectory data are collected from the initial trajectory and the augmented trajectories.

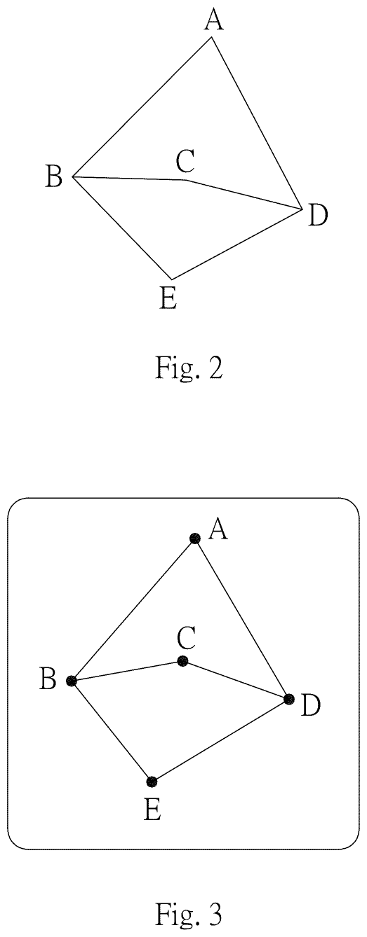

The initial trajectory is a known moving path of an existing mechanism, as shown in FIG. 2.

Each piece of motion trajectory data is the data of a target trajectory (also referred to herein as target-trajectory data), the coordinates of an anchor point (also referred to herein as anchor point coordinates), or the data of an actual executed trajectory (also referred to herein as actual-executed-trajectory data). The target trajectory refers to an expected motion trajectory to be achieved, i.e., the path along which an object is expected to move in space by the user. More specifically, the target trajectory is generally composed of a series of continuous points or curves that describes how an object is supposed to move. The anchor point coordinate are the coordinates of a point that is fixed in space, and are used to limit or guide the motion of an object; in other words, the anchor point coordinate may serve as a reference point for confining or guiding the motion of the object. The actual executed trajectory refers to the path actually taken by an object either during simulation or in an actual motion.

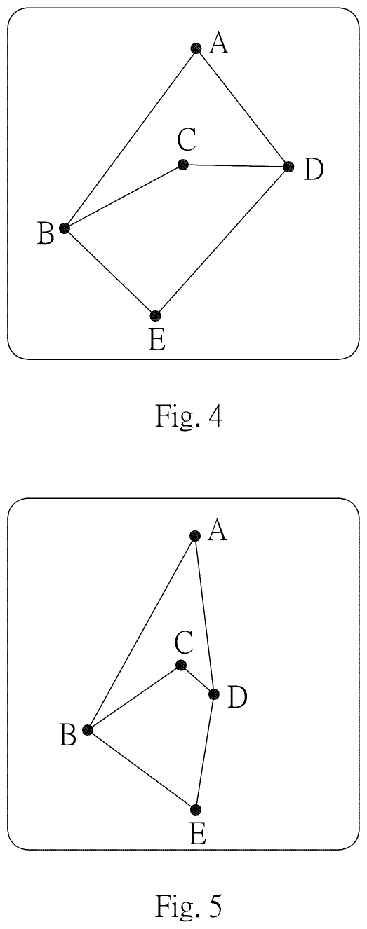

Each augmented trajectory is generated by varying the initial trajectory according to a variate standard and then calculating the average values, maximum values, or minimum values of the resulting variation of the initial trajectory. The variate standard is applied by setting the domain of a random radius differently in order to obtain the calculation results of the average values, maximum values, or minimum values. More specifically, the domain of the random radius is set as from 1 to 1.6 when calculating the minimum values, as shown in FIG. 3; from 1 to 5.4 when calculating the average values, as shown in FIG. 4; and from 1 to 11.2 when calculating the maximum values, as shown in FIG. 5.

Step B: Each piece of motion trajectory data is screened according to a screening criterion in order to eliminate motion trajectory data that falls short of the screening criterion. The screening criterion is applied by determining whether or not there is a non-closed trajectory and whether or not an actuator is deformed. More specifically, a non-closed trajectory refers to a trajectory or path formed by a moving object, wherein the starting point and the endpoint of the trajectory are not connected such that the trajectory is not closed; in other words, the trajectory does not form a complete closed loop but is a series of open paths in space. The actuator generally refers to an object or part to which a force is applied, and deformation refers to a change in shape or structure of the object or part. The actuator being deformed, therefore, refers to a change in shape or structure of an object or part that is subjected to an externally applied force or an acting force.

The screening criterion may alternatively involve such performance indictors as shape integrity, dimensional precision, and the amount of deformation.

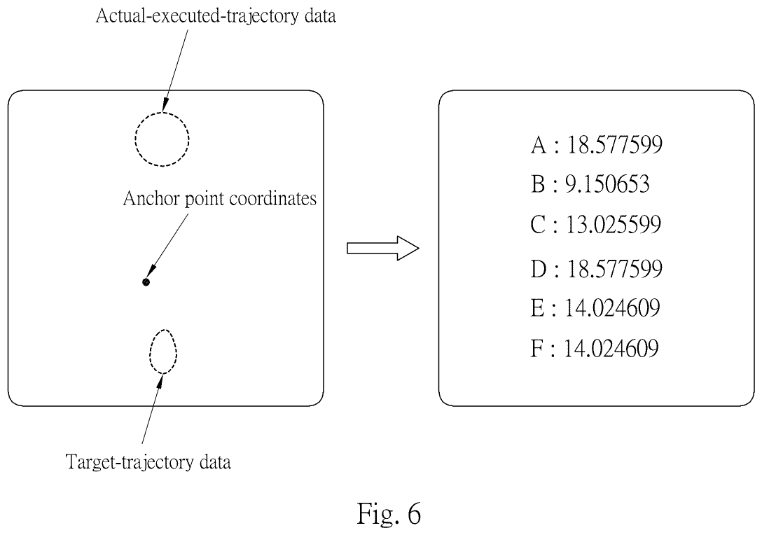

Step C: Referring to FIG. 6, motion trajectory data that conforms to the screening standard is blended to form a diagram. More specifically, the blending process includes: using Rhino Grasshopper software to extract the target-trajectory data, actual-executed-trajectory data, and anchor point coordinate in the motion trajectory data conforming to the screening standard; and creating a trajectory plot based on the extracted data and coordinates, as shown by the left box in FIG. 6. The trajectory plot includes different sets of coordinates that represent the positional information of different portions of a mechanical structure. These sets of coordinates are then combined or integrated to obtain the diagram. The diagram includes at least two nodes (also known as trajectory points) and at least one connecting line connecting the two nodes. The nodes are arranged in a certain order and each represent a point on the initial trajectory or on an augmented trajectory. Moreover, each node includes a physical feature according to which the mechanical structure can be extracted, wherein the physical feature may be a shape, a length, a height, or a width and can be easily extracted with a tool such as Rhino Grasshopper as data with which to generate or train a deep learning model. In the right box in FIG. 6 for example, the physical features denoted by A to E are lengths. The connecting line includes a dynamic characteristic between the two nodes or the positions of and correlation between different trajectories, wherein the dynamic characteristic may be a speed, an acceleration, a displacement, a force received, a mass, a momentum, an angular velocity, a moment of inertia, or an angular acceleration. When there are more than two nodes, the nodes are still arranged in a certain order, with each two adjacent nodes connected by a corresponding connecting line. Thus, the diagram intuitively presents information related to the mechanical structure and its dynamic operation. Take a mechanical linkage system for example. The physical features of the nodes may include the length information of each link, and the dynamic characteristic of each connecting line may include the moving modes or parameters of the corresponding link, such that the diagram provides a comprehensive snapshot of, i.e., visualizes, the motion of the mechanism.

Step D: A tool such as Rhino Grasshopper is used to construct and concretely present a three-dimensional mechanism based on the physical features and the dynamic characteristic, wherein the three-dimensional mechanism may be, but is not limited to, a geometric shape (e.g., a cube, a cylinder, a sphere, or a polygon), a framed structure (e.g., a structural body, a building structure, or a mechanical structure), a mechanical connecting element (e.g., any combination of elements selected from the group consisting of gears, screws, bearings, and links), or a curved-surface structure.

The construction process of the three-dimensional mechanism may include simulating a trajectory offset or rotation of the three-dimensional mechanism in a real-world application scenario while taking into consideration the effect of an external force such as a frictional force, gravity, or other environmental factors that may act on the three-dimensional mechanism during operation and lead to a change or deviation of the corresponding motion trajectory. Simply put, the simulation process includes such steps as collection of actual data, preparation of datasets, fine-tuning training, performance evaluation, and iterative optimization, the goal being to gradually adapt the simulation model to various external factors and uncontrollable factors in real application scenarios, and thereby produce mechanism design recommendations that better suit actual conditions. This helps enhance the practicality and reliability of the present invention so that the invention has satisfactory performance in real applications.

Step E: The three-dimensional mechanism is input into a deep learning model in order to train the model and thereby obtain a trained deep learning model. The deep learning model uses a long short-term memory (LSTM) network and a graph attention network (GAT), which is a variant of the model-visualizing graphic neural network (GNN). Capable of processing time series data, the LSTM network can divide graph data, and allow the data to be input into the network, according to time, thus overcoming the problem of time inconsistency caused by the speed differences among the different motion trajectories in a conventional method, and in consequence, the data is converted into embedded data of a fixed dimension as motion trajectory information.

During the model training process, the input three-dimensional mechanism still includes the physical features and the dynamic characteristic, so the LSTM model can learn with precision the dynamic time-series relationship of the three-dimensional mechanism in a latent space. After that, the GNN model explores in depth the complicated networks described by the three-dimensional mechanism in the latent space in order to generate the modeling information of the model.

Step F: The trained deep learning model is evaluated. To ensure that the model has optimal performance in actual applications, the assessment indicators include those related to prediction accuracy, error rate, and the ability to respond to unseen data.

During the assessment process, four different experimental groups are used in conjunction with a number of assessment indicators such as but not limited to the peak correlation magnitude (PCM), which is used to determine, by way of comparison, the similarity between a simulated result and the corresponding actual data; deformation (DF), which is used to evaluate the degree of deformation of an actuator, i.e., the degree to which the shape of an object has changed under the action of an external force; area, which refers to the surface area of an object and is used to evaluate a shape-related or structural feature of the object; curvature length (CL), which refers to the curvature length of a curved line or curved surface and is used to evaluate the change in curvature of an object; dynamic time warping (DTW), which is used to determine, by way of comparison, the similarity between the motion trajectories of an object or the difference between different emulated scenarios; mean absolute error (MAE), which refers to the mean absolute error between a predicted value and the corresponding actual value and is used to evaluate the accuracy or prediction ability of the model; and mean squared error (MSE), which refers to the mean squared error between a predicted value and the corresponding actual value and is used to evaluate model accuracy. The MAE values of the experimental groups are in the range from 0.18 to 1.99, meaning the model has a relatively good prediction effect.

Step G: A user is allowed to input a target trajectory into the trained deep learning model in order for the trained deep learning model to generate the data of a target mechanism. The data of the target mechanism will vary with the input target trajectory to satisfy specific design requirements. The data of the target mechanism includes structural features (e.g., lines, curved lines, polygons, a three-dimensional object, a framed structure, a grid structure, and/or a curved-surface structure) and a moving behavior (e.g., a motion trajectory, a deformation movement, and/or a vibration).

The preferred embodiment described above serves only to expound the present invention. Any simple modification or change that is made to the foregoing embodiment by a person skilled in the art without departing from the spirit of the invention or is easily conceivable by a person skilled in the art shall fall within the scope of the appended claims.

What is claimed is:

1. A method of mechanism generation based on a trajectory, comprising:
step A: generating a plurality of augmented trajectories based on an initial trajectory, and collecting a plurality of pieces of motion trajectory data from the initial trajectory and the augmented trajectories;
step B: screening each piece of said motion trajectory data according to a screening criterion in order to eliminate said motion trajectory data falling short of the screening criterion;
step C: forming a diagram by blending said motion trajectory data conforming to the screening criterion, wherein the diagram comprises at least two nodes and at least one connecting line connecting the two nodes, each said node includes a physical feature, and the connecting line includes a dynamic characteristic between the two nodes; and
step D: constructing a three-dimensional mechanism based on the physical features and the dynamic characteristic.

2. The method of mechanism generation based on a trajectory as claimed in claim 1, wherein each piece of said motion trajectory data in the step A is target-trajectory data, an anchor point coordinate, or an actual-executed-trajectory data; and said blending in the step C comprises creating a trajectory plot from the target-trajectory data, the actual-executed-trajectory data, and the anchor point coordinate in said motion trajectory data conforming to the screening criterion, and then combining or integrating multiple sets of coordinates in the trajectory plot to obtain the diagram.

3. The method of mechanism generation based on a trajectory as claimed in claim 1, wherein each said augmented trajectory in the step A is generated by varying the initial trajectory according to a variate standard and calculating average values, maximum values, or minimum values of a resulting variation of the initial trajectory.

4. The method of mechanism generation based on a trajectory as claimed in claim 3, wherein the variate standard is applied by setting a domain of a random radius differently in order to obtain calculation results of the average values, of the maximum values, or of the minimum values; and the domain of the random radius is set as from 1 to 5.4 when calculating the average values, from 1 to 1.6 when calculating the minimum values, and from 1 to 11.2 when calculating the maximum values.

5. The method of mechanism generation based on a trajectory as claimed in claim 1, wherein the screening criterion in the step B is applied by determining whether or not there is a non-closed trajectory and whether or not an actuator is deformed.

6. The method of mechanism generation based on a trajectory as claimed in claim 1, wherein each said physical feature is a shape, a length, a height, or a width.

7. The method of mechanism generation based on a trajectory as claimed in claim 1, wherein the dynamic characteristic is a speed, an acceleration, a displacement, a force, a mass, a momentum, an angular velocity, a moment of inertia, or an angular acceleration.

8. The method of mechanism generation based on a trajectory as claimed in claim 1, further comprising a step E to be performed after the step D, wherein the step E comprises inputting the three-dimensional mechanism into a deep learning model in order to train the deep learning model and thereby obtain a trained deep learning model.

9. The method of mechanism generation based on a trajectory as claimed in claim 8, further comprising a step F to be performed after the step E, wherein the step F comprises evaluating the trained deep learning model.

10. The method of mechanism generation based on a trajectory as claimed in claim 8, further comprising a step G to be performed after the step E, wherein the step G comprises allowing a user to input a target trajectory into the trained deep learning model in order for the trained deep learning model to generate data of a target mechanism.

11. The method of mechanism generation based on a trajectory as claimed in claim 2, wherein each said augmented trajectory in the step A is generated by varying the initial trajectory according to a variate standard and calculating average values, maximum values, or minimum values of a resulting variation of the initial trajectory.

12. The method of mechanism generation based on a trajectory as claimed in claim 11, wherein the variate standard is applied by setting a domain of a random radius differently in order to obtain calculation results of the average values, of the maximum values, or of the minimum values; and the domain of the random radius is set as from 1 to 5.4 when calculating the average values, from 1 to 1.6 when calculating the minimum values, and from 1 to 11.2 when calculating the maximum values.
